(19) United States
(12) Patent Application Publication
(10) Pub. No.: US 2024/0431149 A1
(43) Pub. Date: Dec. 26, 2024

(54) DISPLAY DEVICE

(71) Applicant: Japan Display Inc., Tokyo (JP)

(72) Inventor: Hideyuki TAKAHASHI, Tokyo (JP)

(73) Assignee: Japan Display Inc., Tokyo (JP)

(21) Appl. No.: 18/738,230

(22) Filed: Jun. 10, 2024

(30) Foreign Application Priority Data
Jun. 26, 2023 (JP) 2023-104290

(51) Int. Cl. H10K 59/122

(52) U.S. Cl. CPC H10K 59/122

(57) ABSTRACT

According to one embodiment, a display device includes first and second areas including subpixels, and a partition including a conductive lower portion and an upper portion. Each of the subpixels includes a lower electrode, an organic layer which covers the lower electrode and emits light based on application of voltage, and an upper electrode which covers the organic layer and is in contact with the lower portion of the partition. The second area has a plurality of transmissive areas which are surrounded by the partition and do not overlap the lower electrode. A resolution of the second area is lower than a resolution of the first area.

### CROSS-REFERENCE TO RELATED APPLICATION

This application is based upon and claims the benefit of priority from Japanese Patent Application No. 2023-104290, filed Jun. 26, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area.

In some cases, translucency is required in at least part of the display area in which the display elements are arrayed. However, if the above lower electrodes and lines are formed of a material having light-shielding properties such as metal, the translucency of the display device could be considerably decreased.

### BRIEF DESCRIPTION OF THE DRAWINGS

FIG. 1 is a diagram showing a configuration example of a display device according to a first embodiment.

FIG. 2 is a schematic plan view showing an example of the layout of the subpixels of a first area according to the first embodiment.

FIG. 3 is a schematic cross-sectional view of the display device along the III-III line of FIG. 2.

FIG. 4 is a schematic plan view of a second area according to the first embodiment.

FIG. 5 is a schematic cross-sectional view of the display device along the V-V line of FIG. 4.

FIG. 6 is a schematic cross-sectional view showing another example which can be applied to a transmissive area included in the second area.

FIG. 7 is a schematic cross-sectional view showing yet another example which can be applied to the transmissive area.

FIG. 8 is a schematic cross-sectional view showing yet another example which can be applied to the transmissive area.

FIG. 9 is a schematic cross-sectional view showing yet another example which can be applied to the transmissive area.

FIG. 10 is a schematic plan view in which

part of the second area is enlarged according to the first embodiment.

FIG. 11 is a schematic plan view of a second area according to a second embodiment.

FIG. 12 is a schematic plan view of a second area according to a third embodiment.

FIG. 13 is a schematic plan view of two subpixels included in the second area according to the third embodiment.

FIG. 14 is a schematic cross-sectional view of a display device along the XIV-XIV line of FIG. 13.

FIG. 15 is a schematic plan view of a second area according to a fourth embodiment.

FIG. 16 is a schematic plan view of a second area according to a fifth embodiment.

FIG. 17 is a schematic plan view of a second area according to a sixth embodiment.

### DETAILED DESCRIPTION

In general, according to one embodiment, a display device comprises first and second areas each of which includes a plurality of subpixels, and a partition which includes a conductive lower portion and an upper portion having an end portion protruding from a side surface of the lower portion, and surrounds each of the subpixels. Each of the subpixels includes a lower electrode, an organic layer which covers the lower electrode and emits light based on application of voltage, and an upper electrode which covers the organic layer and is in contact with the lower portion of the partition. The second area has a plurality of transmissive areas which are surrounded by the partition and do not overlap the lower electrode. Further, a resolution of the second area is lower than a resolution of the first area.

According to another aspect of the embodiment, the subpixels include a first subpixel provided in the first area, and a second subpixel provided in the second area and displaying a same color as the first subpixel. Further, the first subpixel and the second subpixel have shapes or sizes different from each other.

According to yet another aspect of the embodiment, a display device comprises a lower electrode, a first organic layer which covers the lower electrode and emits light based on application of voltage, a second organic layer which is spaced apart from the first organic layer, covers the lower electrode and emits light based on application of voltage, a partition which includes a conductive lower portion and an upper portion having an end portion protruding from a side surface of the lower portion and is at least partly located between the first organic layer and the second organic layer, a first upper electrode which covers the first organic layer and is in contact with the lower portion, and a second upper electrode which covers the second organic layer and is in contact with the lower portion.

The embodiments can provide a display device with excellent translucency.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

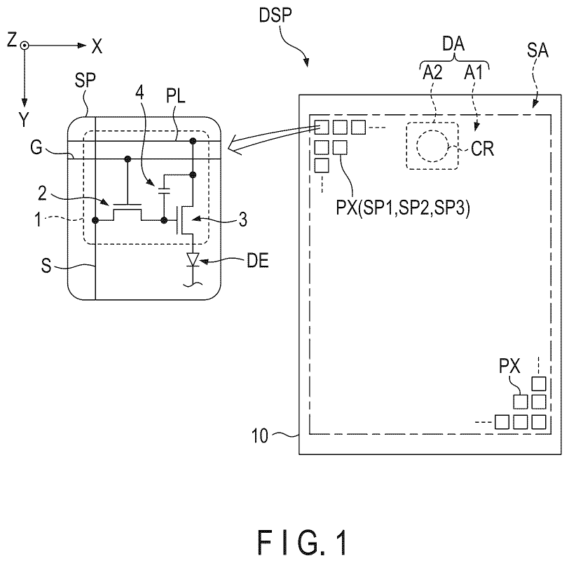

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In this embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply a scanning signal to the pixel circuit 1 of each subpixel SP, a plurality of signal lines S which supply a video signal to the pixel circuit 1 of each subpixel SP and a plurality of power lines PL are provided. In the example of FIG. 1, the scanning lines G and the power lines PL extend in the X-direction, and the signal lines S extend in the Y-direction.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

The display area DA includes a first area A1 and a second area A2 having a translucency which is higher than the first area A1. For example, a camera CR is provided on the back surface side of the second area A2. This camera CR can capture the target object located on the display surface side through the second area A2. In place of the camera CR, another type of photoreceiver such as an illumination sensor which detects external light may be provided. The display area DA may include a plurality of second areas A2 facing the camera CR and the illumination sensor.

For example, the second area A2 is smaller than the first area A1. In the example of FIG. 1, the second area A2 is located near an end portion of the display area DA and is surrounded by the first area A1. However, the layout position of the second area A2 is not limited to this example. The second area A2 may not be necessarily surrounded by the first area A1 in the whole circumference and may be provided such that one side or two sides face the surrounding area SA. The second area A2 is, for example, rectangular. However, the second area A2 may have another shape such as a circular shape.

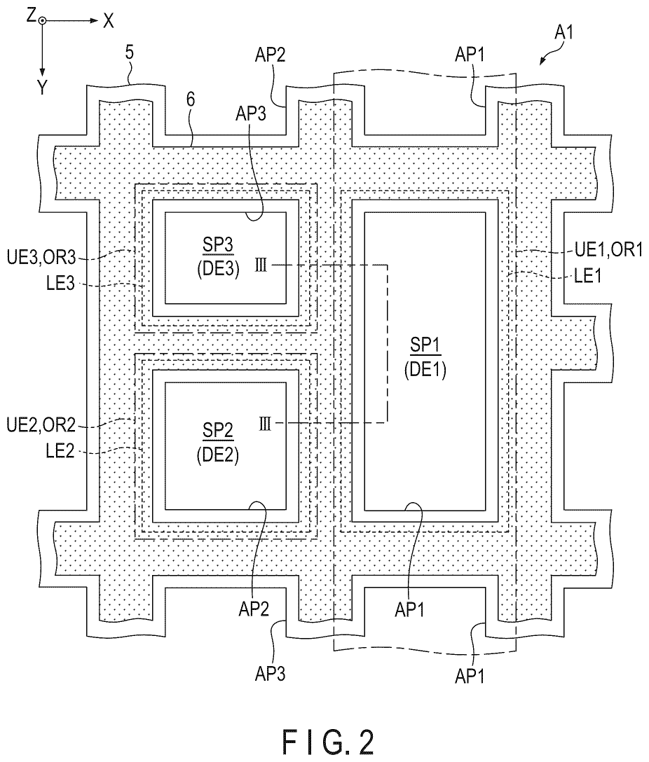

FIG. 2 is a schematic plan view showing an example of the layout of subpixels SP1, SP2 and SP3 in the first area A1. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has a planar shape similar to that of the rib 5. In other words, the partition 6 has an aperture in each of subpixels SP1, SP2 and SP3. From another viewpoint, each of the rib 5 and the partition 6 has a grating shape as seen in plan view and surrounds each of subpixels SP1, SP2 and SP3. The partition 6 functions as lines which apply common voltage to the upper electrodes UE1, UE2 and UE3.

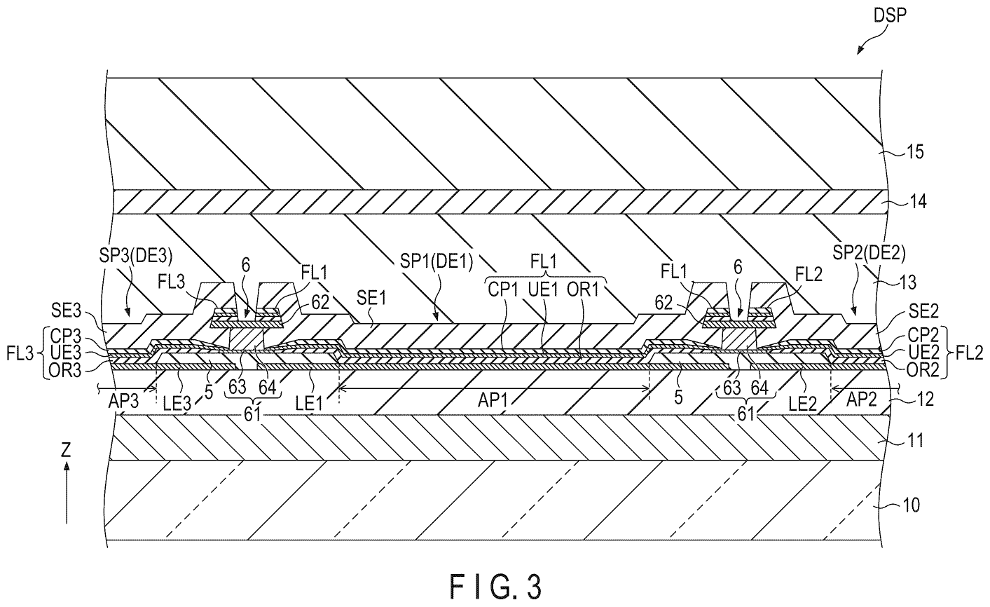

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the cap layer CP1 and the partition 6 around subpixel SP1. The sealing layer SE2 continuously covers the cap layer CP2 and the partition 6 around subpixel SP2. The sealing layer SE3 continuously covers the cap layer CP3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (Al₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

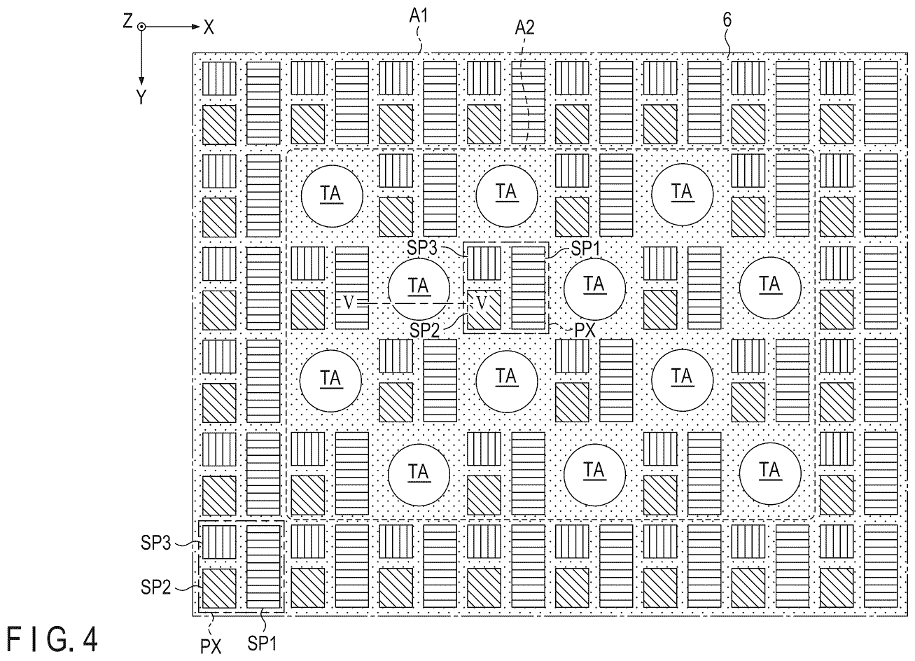

FIG. 4 is a schematic plan view showing the second area A2 and part of the first area A1 which surrounds the second area A2. The dotted portion of the figure corresponds to the partition 6. In the first area A1, a plurality of subpixels SP1, SP2 and SP3 are provided in line with the layout shown in FIG. 2. Subpixels SP1 are shown by the pattern of lateral stripes. Subpixels SP2 are shown by the pattern of diagonal stripes. Subpixels SP3 are shown by the pattern of vertical stripes.

The second area A2 has a plurality of transmissive areas TA. The transmissive areas TA are surrounded by the partition 6. From another viewpoint, the partition 6 has a plurality of apertures corresponding to the transmissive areas TA. In the example of FIG. 4, the first area A1 does not have any transmissive area TA. As another example, the first area A1 may have at least one transmissive area TA.

In the example of FIG. 4, the shape of each transmissive area TA is a circle as seen in plan view. However, the shape is not limited to this example. Each transmissive area TA may have another shape such as a rectangle. The size of each transmissive area TA is not particularly limited. However, for example, each transmissive area TA has a larger area than the smallest subpixel (in the example of FIG. 4, subpixel SP3) among subpixels SP1, SP2 and SP3. Each transmissive area TA may have a larger area than each of subpixels SP1, SP2 and SP3.

In a manner similar to that of the first area A1, subpixels SP1, SP2 and SP3 are provided in the second area A2. In the example of FIG. 4, subpixels SP1, SP2 and SP3 provided in the first area A1 have the same shapes and sizes as subpixels SP1, SP2 and SP3 provided in the second area A2.

The resolution (the density of subpixels SP1, SP2 and SP3) of the second area A2 is lower than that of the first area A1 in each of the X-direction and the Y-direction. In the example of FIG. 4, the resolution of the second area A2 is half that of the first area A1 in each of the X-direction and the Y-direction.

From another viewpoint, pixels PX are thinned out in the second area A2 compared to the first area A1. The transmissive areas TA are provided in the spaces generated by this thinning out. In the example of FIG. 4, each transmissive area TA and each pixel PX are alternately arranged in each of the X-direction and the Y-direction.

It should be noted that the shape and size of the second area A2 shown in FIG. 4 are merely examples. The second area A2 may include more pixels PX and transmissive areas TA than the example of FIG. 4. Alternatively, the second area A2 may include less pixels PX and transmissive areas TA than the example of FIG. 4.

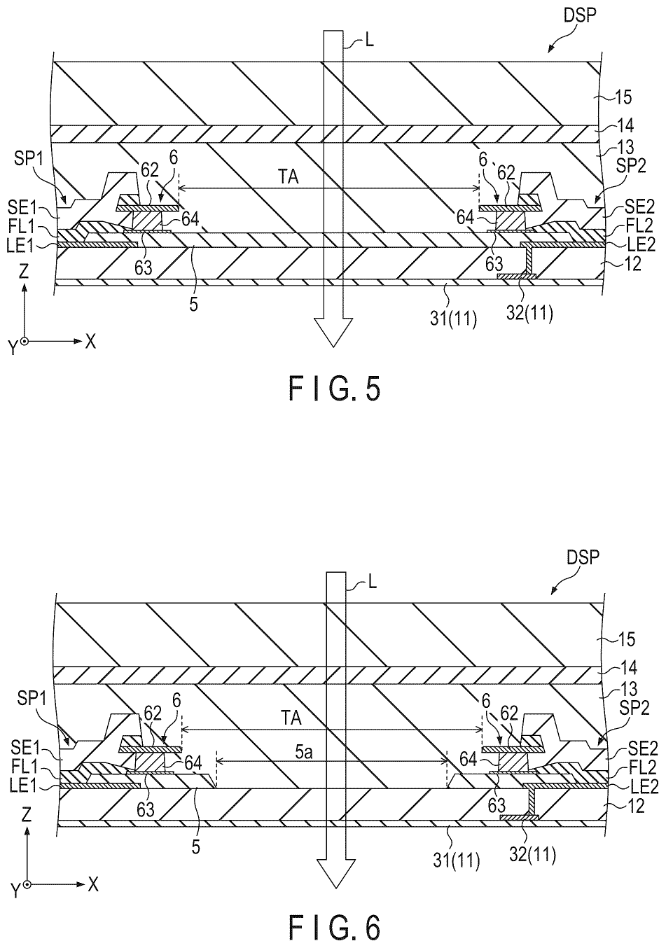

FIG. 5 is a schematic cross-sectional view of the display device DSP along the V-V line of FIG. 4. The circuit layer 11 shown in FIG. 3 includes an inorganic insulating layer 31, and a metal line 32 provided on the inorganic insulating layer 31. The inorganic insulating layer 31 and the line 32 are covered with, for example, the organic insulating layer 12. It should be noted that the portion located on the lower side than the inorganic insulating layer 31 in the circuit layer 11 and the substrate 10 are omitted in FIG. 5.

In the example of FIG. 5, the transmissive area TA overlaps the organic insulating layer 12 and the rib 5. None of the lower electrodes LE1, LE2 and LE3, the stacked films FL1, FL2 and FL3 and the sealing layers SE1, SE2 and SE3 is provided in the transmissive area TA. The resin layer 13 covers the rib 5 in the transmissive area TA.

In this configuration, external light L which enters the display surface of the display device DSP passes through the transmissive area TA to the back surface side. To the contrary, external light L is blocked by the partition 6, the lower electrodes LE1, LE2 and LE3 and the like in areas other than the transmissive area TA.

As described in detail later, the line 32 applies pixel voltage to subpixels SP1, SP2 and SP3 provided in the second area A2. In the example of FIG. 5, the lower electrode LE2 of subpixel SP2 is in contact with the line 32 through a contact hole provided in the organic insulating layer 12. To increase the translucency in the transmissive area TA, the various lines (for example, the line 32 and the scanning lines G, signal lines S and power lines PL shown in FIG. 1) included in the circuit layer 11 should not preferably overlap the transmissive area TA. However, part of these lines may overlap the transmissive area TA.

FIG. 6 is a schematic cross-sectional view showing another example which can be applied to the transmissive area TA. In the example of this figure, the rib 5 has an aperture 5a in the transmissive area TA. The resin layer 13 is in contact with the organic insulating layer 12 through the aperture 5a. The aperture 5a has, for example, a planar shape (for example, a circular shape) which is similar to that of the transmissive area TA.

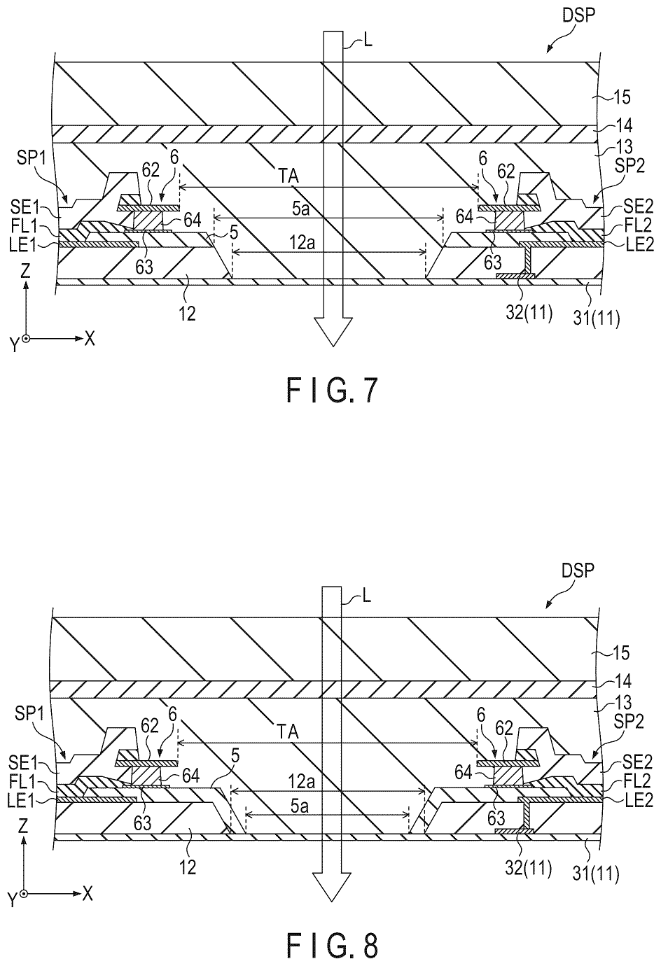

FIG. 7 is a schematic cross-sectional view showing yet another example which can be applied to the transmissive area TA. In the example of this figure, in the transmissive area TA, the rib 5 has an aperture 5a, and further, the organic insulating layer 12 has an aperture 12a. The aperture 12a has, for example, a planar shape (for example, a circular shape) which is similar to that of the transmissive area TA.

In the example of FIG. 7, the aperture 5a is slightly larger than the aperture 12a. The rim of the rib 5 along the aperture 5a is located on the organic insulating layer 12. The resin layer 13 is in contact with the inorganic insulating layer 31 through the apertures 5a and 12a.

FIG. 8 is a schematic cross-sectional view showing yet another example which can be applied to the transmissive area TA. In a manner similar to that of the example of FIG. 7, the rib 5 has an aperture 5a, and the organic insulating layer 12 has an aperture 12a. However, the aperture 5a is slightly smaller than the aperture 12a in the example of FIG. 8. The rim of the organic insulating layer 12 along the aperture 12a is covered with the rib 5.

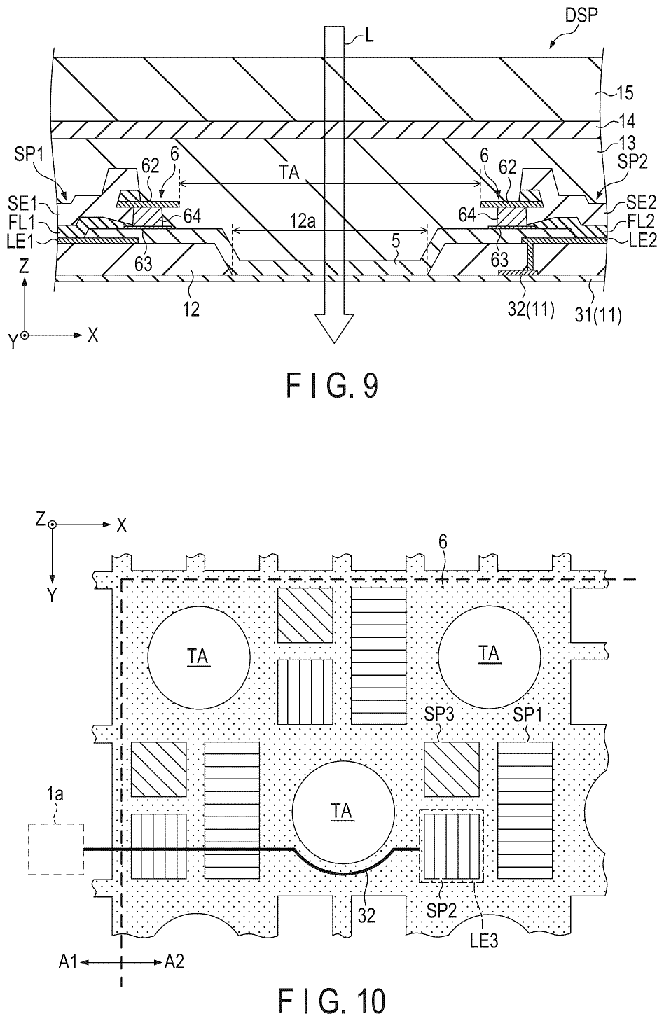

FIG. 9 is a schematic cross-sectional view showing yet another example which can be applied to the transmissive area TA. In a manner similar to that of the examples of FIG. 7 and FIG. 8, the organic insulating layer 12 has an aperture 12a. It should be noted that the rib 5 does not have an aperture 5a in the example of FIG. 9. The rim of the organic insulating layer 12 along the aperture 12a is covered with the rib 5.

The translucency of the transmissive area TA can be increased by removing at least one of the rib 5 and the organic insulating layer 12 in the transmissive area TA as shown in FIG. 6 to FIG. 9. In a case where the rim of the organic insulating layer 12 is covered with the rib 5 as shown in FIG. 8 and FIG. 9, for example, the organic insulating layer 12 can be protected from etching when the partition 6 and the stacked films FL1, FL2 and FL3 are patterned.

FIG. 10 is a schematic plan view in which part of the second area A2 is enlarged. At least one of the pixel circuits 1 (see FIG. 1) of subpixels SP1, SP2 and SP3 provided in the second area A2 may be provided in the first area A1. By decreasing the number of pixel circuits 1 provided in the second area A2 in this manner, the layout of the second area A2 is made more efficient, and a wide space can be secured to provide the transmissive areas TA.

In the example of FIG. 10, a pixel circuit 1a for applying voltage to the lower electrode LE2 of subpixel SP2 of the second area A2 is provided in the first area A1. These lower electrode LE2 and pixel circuit 1a are connected to each other by the line 32 which is also shown in the sections of FIG. 5 to FIG. 9. Regarding subpixels SP1 and SP3 of the second area A2, similarly, the pixel circuits 1 for applying voltage to their lower electrodes LE1 and LE3 may be provided in the first area A1.

It is preferable that the line 32 should not overlap the transmissive areas TA. In the example of FIG. 10, part of the line 32 is curved to avoid the transmissive area TA. In a manner similar to that of the line 32, part of the scanning lines G, signal lines S and power lines PL passing through the second area A2 may be curved to avoid the transmissive areas TA.

In the embodiment described above, the display area DA has the second area A2 including the transmissive areas TA. By this configuration, the camera CR shown in FIG. 1 and the like can be provided to overlap the display area DA. In addition, in the embodiment, subpixels SP1, SP2 and SP3 are provided in the second area A2 as well. This configuration allows the second area A2 to perform image display similar to that of the first area A1.

If each transmissive area TA includes a linear outer shape, halation easily occurs in images captured by the camera CR. To the contrary, when each transmissive area TA is circular as shown in FIG. 4 or has another curved outer shape, halation can be prevented. In the embodiment, the outer shape of each transmissive area TA is mainly defined by the light-shielding partition 6. In this case, the degree of freedom of the shape of each transmissive area TA in designing is increased.

The configuration of subpixel SP1, SP2 or SP3 or each transmissive area TA in the second area A2 is not limited to the configurations disclosed in this embodiment. The second to sixth embodiments described below disclose other configurations which can be applied to the second area A2. The configurations disclosed in the first embodiment (for example, the configurations shown in FIG. 1 to FIG. 3 and FIG. 5 to FIG. 10) can be also applied to the other embodiments. In each of the following embodiments, the same structural elements as the first embodiment are denoted by the same reference numbers. Thus, overlapping descriptions are omitted.

### Second Embodiment

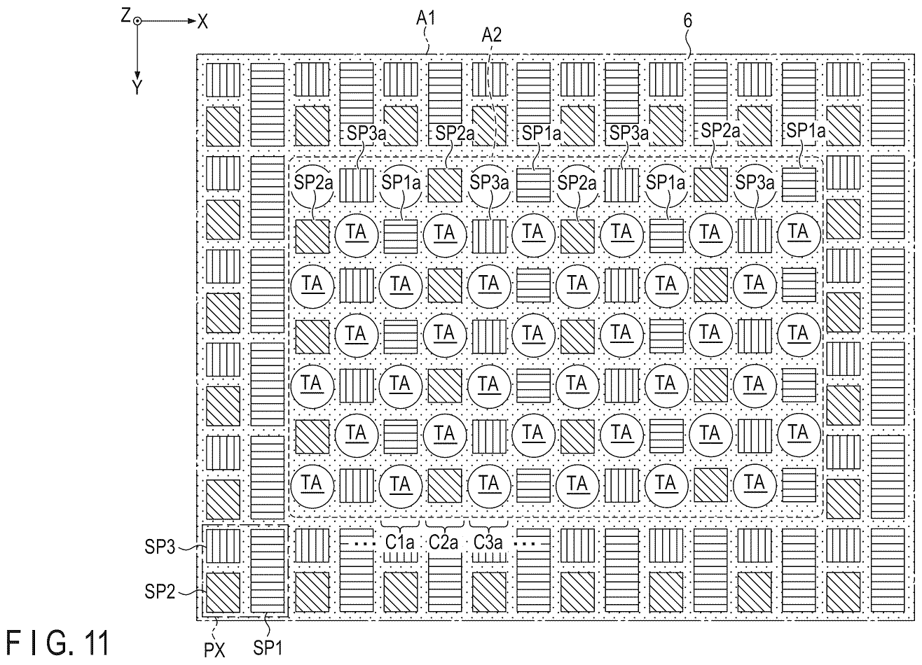

FIG. 11 is a schematic plan view showing a second area A2 and part of a first area A1 which surrounds the second area A2 according to the second embodiment. In a manner similar to that of FIG. 4, a partition 6 is shown by the dotted pattern. Subpixels SP1 are shown by the pattern of lateral stripes. Subpixels SP2 are shown by the pattern of diagonal stripes. Subpixels SP3 are shown by the pattern of vertical stripes.

In this embodiment, subpixels SP1, SP2 and SP3 provided in the second area A2 are called subpixels SP1a, SP2a and SP3a, respectively. In the example of FIG. 11, all of subpixels SP1a, SP2a and SP3a have rectangular shapes with the same size. It should be noted that the size of each subpixel corresponds to the area of the aperture of the partition 6 in the subpixel in plan view, more specifically, the area of the region surrounded by the upper portion 62 of the partition 6 in plan view.

In the example of FIG. 11, the sizes of blue subpixels SP1 and SP1a are different from each other. The sizes of green subpixels SP2 and SP2a are also different from each other. The sizes of red subpixels SP3 and SP3a are equal to each other in FIG. 11. However, they may be different from each other.

For example, the sizes of subpixels SP1a, SP2a and SP3a are equal to each other. In this case, the sizes of subpixels SP1a and SP2a provided in the second area A2 are smaller than those of subpixels SP1 and SP2 provided in the first area A1.

In the second area A2 of FIG. 11, each transmissive area TA is provided, of a plurality of subpixels SP1a, SP2a and SP3a, between two subpixels which are adjacent to each other in an X-direction and between two subpixels which are adjacent to each other in a Y-direction. More specifically, the second area A2 includes columns C1a in which each subpixel SP1a and each transmissive area TA are alternately provided in the Y-direction, columns C2a in which each subpixel SP2a and each transmissive area TA are alternately provided in the Y-direction, and columns C3a in which each subpixel SP3a and each transmissive area TA are alternately provided in the Y-direction. The columns C1a, C2a and C3a are repeatedly arranged in the X-direction. The pitch at which the columns C1a, C2a and C3a are arranged in the X-direction is equal to the pitch at which subpixels SP1 and SP2 (or subpixels SP1 and SP3) are arranged in the X-direction.

The shape of each transmissive area TA is, for example, a circle in a manner similar to that of FIG. 4. However, the shape of each transmissive area TA may be another shape. The transmissive areas TA in FIG. 11 are smaller than those of the example of FIG. 4. Further, more transmissive areas TA are provided in the second area A2 than the example of FIG. 4.

When the sizes of the subpixels provided in the second area A2 are different from those of the subpixels provided in the first area A1 as in the case of this embodiment, the degree of freedom of the layout of the transmissive areas TA in the second area A2 can be increased. By this configuration, for example, the transmissive areas TA can be made as large as possible, and thus, the translucency of the second area A2 can be improved.

### Third Embodiment

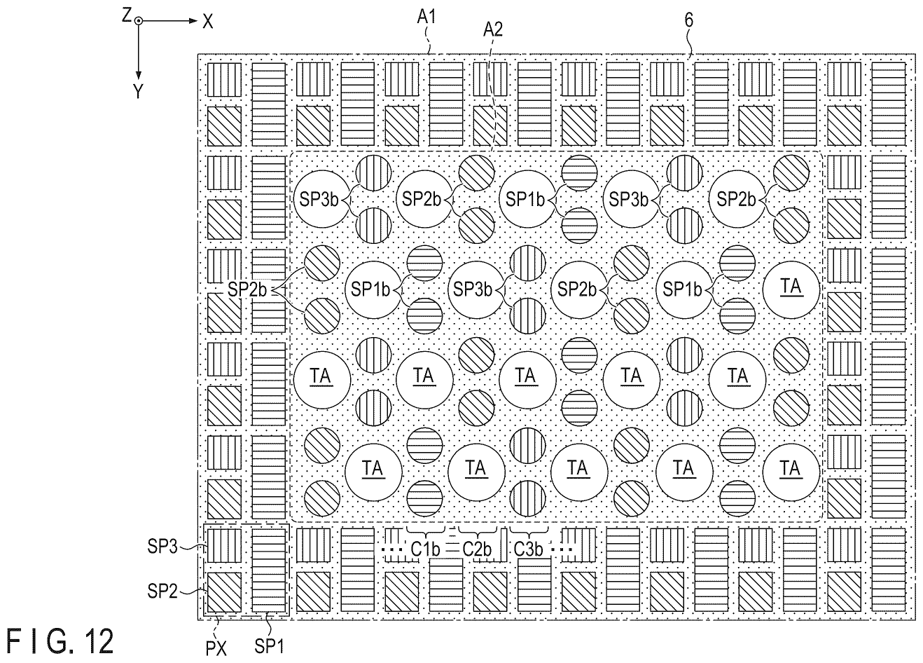

FIG. 12 is a schematic plan view showing a second area A2 and part of a first area A1 which surrounds the second area A2 according to the third embodiment. In a manner similar to that of FIG. 4, a partition 6 is shown by the dotted pattern. Subpixels SP1 are shown by the pattern of lateral stripes. Subpixels SP2 are shown by the pattern of diagonal stripes. Subpixels SP3 are shown by the pattern of vertical stripes.

In this embodiment, subpixels SP1, SP2 and SP3 provided in the second area A2 are called subpixels SP1b, SP2b and SP3b, respectively. In the example of FIG. 12, subpixels SP1b, SP2b and SP3b have shapes different from those of subpixels SP1, SP2 and SP3, respectively.

Specifically, subpixels SP1, SP2 and SP3 are rectangular, and subpixels SP1b, SP2b and SP3b are circular. For example, the sizes (diameters) of subpixels SP1b, SP2b and SP3b are equal to each other. However, they may be different from each other.

In the example of FIG. 12, the second area A2 includes columns C1b in which two subpixels SP1b and a transmissive area TA are alternately provided in a Y-direction, columns C2b in which two subpixels SP2b and a transmissive area TA are alternately provided in the Y-direction, and columns C3b in which two subpixels SP3b and a transmissive area TA are alternately provided in the Y-direction. The columns C1b, C2b and C3b are repeatedly arranged in an X-direction. The shape of each transmissive area TA is, for example, a circle in a manner similar to that of FIG. 4. However, the shape of each transmissive area TA may be another shape.

When the shapes of the subpixels provided in the second area A2 are different from those of the subpixels provided in the first area A1 as in the case of this embodiment, similarly, the degree of freedom of the layout of the transmissive areas TA in the second area A2 can be increased. By this configuration, for example, the transmissive areas TA can be made as large as possible, and thus, the translucency of the second area A2 can be improved.

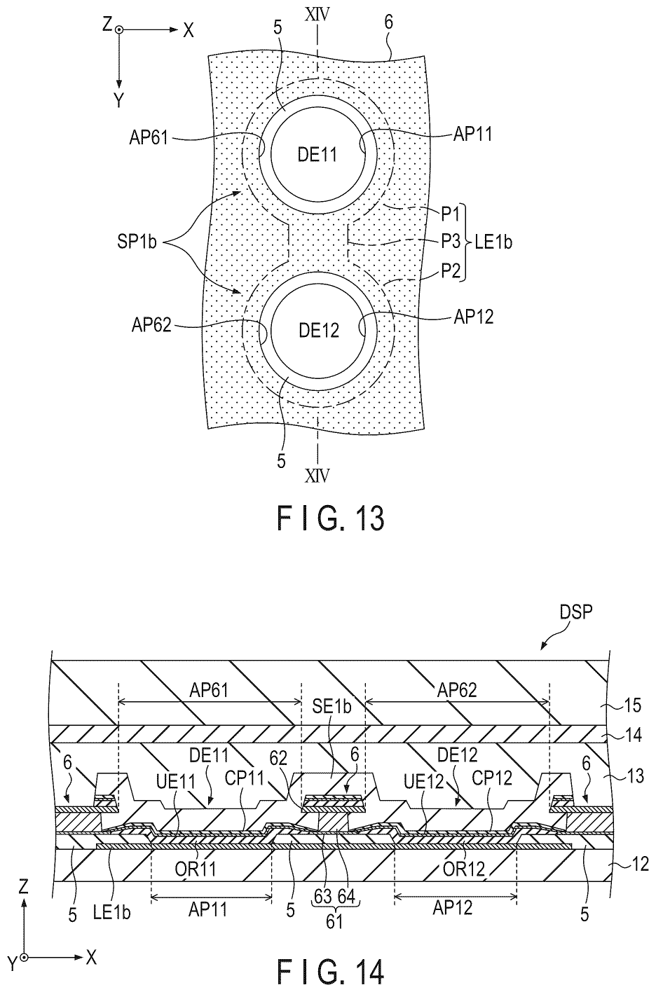

FIG. 13 is a schematic plan view of two subpixels SP1b arranged in the Y-direction. In the following explanation, the display element of one of subpixels SP1b is called a first display element DE11, and the display element of the other subpixel SP1b is called a second display element DE12.

A rib 5 has a first pixel aperture AP11 which surrounds the first display element DE11 and a second pixel aperture AP12 which surrounds the second display element DE12. In the example of FIG. 13, both the pixel aperture AP11 and the pixel aperture AP12 are circular.

The partition 6 has a first aperture AP61 which surrounds the first pixel aperture AP11 and a second aperture AP62 which surrounds the second pixel aperture AP12. In the example of FIG. 13, these apertures AP61 and AP62 are circular in a manner similar to that of the pixel apertures AP11 and AP12. The display elements DE11 and DE12 have a common lower electrode LE1b. In the example of FIG. 13, the lower electrode LE1b has a first part P1 which overlaps the first pixel aperture AP11, a second part P2 which overlaps the second pixel aperture AP12, and a third part P3 which connects the first part P1 and the second part P2. The first part P1 and the second part P2 are, for example, circular. For example, the width of the third part P3 in the X-direction is less than the width (diameter) of each of the first part P1 and the second part P2 in the X-direction.

FIG. 14 is a schematic cross-sectional view of a display device DSP along the XIV-XIV line of FIG. 13. The first display element DE11 has a first organic layer OR11 which covers the lower electrode LE1b through the first pixel aperture AP11, a first upper electrode UE11 which covers the first organic layer OR11, and a first cap layer CP11 which covers the first upper electrode UE11. The second display element DE12 has a second organic layer OR12 which covers the lower electrode LE1b through the second pixel aperture AP12, a second upper electrode UE12 which covers the second organic layer OR12, and a second cap layer CP12 which covers the second upper electrode UE12.

The first organic layer OR11, the first upper electrode UE11 and the first cap layer CP11 overlap the first aperture AP61 of the partition 6. The second organic layer OR12, the second upper electrode UE12 and the second cap layer CP12 overlap the second aperture AP62 of the partition 6.

The upper electrodes UE11 and UE12 are in contact with at least one of the bottom layer 63 and stem layer 64 of the partition 6. The first organic layer OR11 emits blue light based on the potential difference between the lower electrode LE1b and the first upper electrode UE11. Similarly, the second organic layer OR12 emits blue light based on the potential difference between the lower electrode LE1b and the second upper electrode UE12.

Part of the partition 6 is located between the display elements DE11 and DE12. In other words, the organic layers OR11 and OR12 are spaced apart from each other via the partition 6. Similarly, the upper electrodes UE11 and UE12 are spaced apart from each other, and the cap layers CP11 and CP12 are spaced apart from each other. The display elements DE11 and DE12 and the partition 6 between them are continuously covered with a sealing layer SE1b.

In this configuration, the display elements DE11 and DE12 can be driven by a single pixel circuit 1 (see FIG. 1). Thus, even when this pixel circuit 1 is provided in the second area A2, a wide space can be secured to provide the transmissive areas TA.

It should be noted that a configuration similar to that of subpixels SP1b shown in FIG. 13 and FIG. 14 can be applied to both two subpixels SP2b arranged in the Y-direction in FIG. 12 and two subpixels SP3b arranged in the Y-direction in FIG. 12.

### Fourth Embodiment

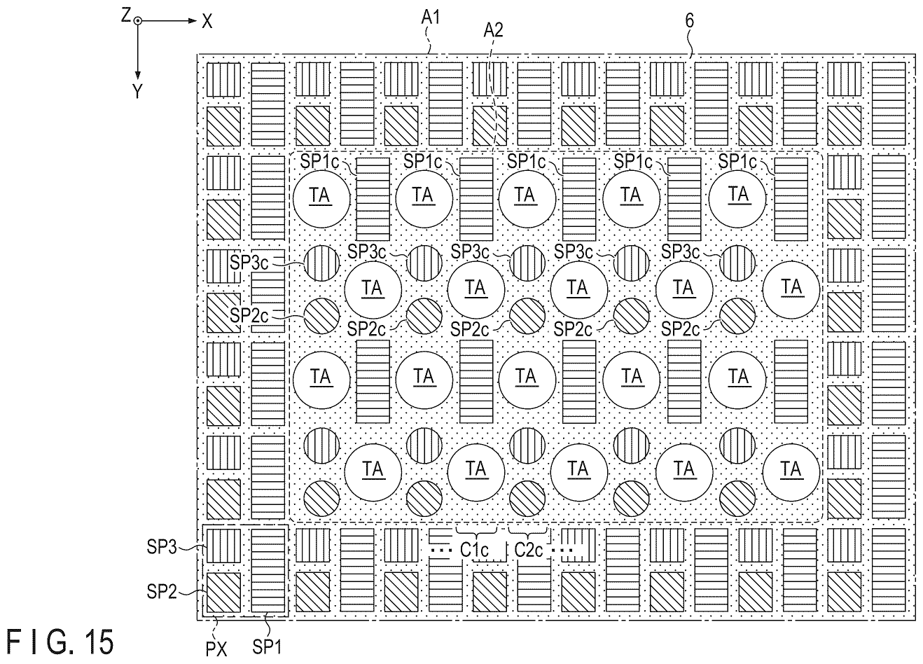

FIG. 15 is a schematic plan view showing a second area A2 and part of a first area A1 which surrounds the second area A2 according to the fourth embodiment. In a manner similar to that of FIG. 4, a partition 6 is shown by the dotted pattern. Subpixels SP1 are shown by the pattern of lateral stripes. Subpixels SP2 are shown by the pattern of diagonal stripes. Subpixels SP3 are shown by the pattern of vertical stripes.

In this embodiment, subpixels SP1, SP2 and SP3 provided in the second area A2 are called subpixels SP1c, SP2c and SP3c, respectively. In the example of FIG. 15, each subpixel SP1 and each subpixel SP1c have the same shape and size. However, subpixels SP2c and SP3c have shapes which are different from those of subpixels SP2 and SP3, respectively.

Specifically, subpixels SP1, SP2, SP3 and SP1c are rectangular, and subpixels SP2c and SP3c are circular. For example, the sizes (diameters) of subpixels SP2c and SP3c are equal to each other. However, they may be different from each other.

In the example of FIG. 15, the second area A2 includes columns C1c in which each subpixel SP1c and each transmissive area TA are alternately provided in a Y-direction, and columns C2c in which subpixels SP3c and SP2c and each transmissive area TA are alternately provided in the Y-direction. The columns C1c and C2c are repeatedly arranged in an X-direction. The shape of each transmissive area TA is, for example, a circle in a manner similar to that of FIG. 4. However, the shape of each transmissive area TA may be another shape.

In the example of FIG. 15, the size of each subpixel SP1c is larger than that of each of subpixels SP2c and SP3c. This relationship of the sizes is similar to that of the sizes between each subpixel SP1 and subpixels SP2 and SP3. This configuration enables the reduction in the difference in the display quality between the first area A1 and the second area A2.

### Fifth Embodiment

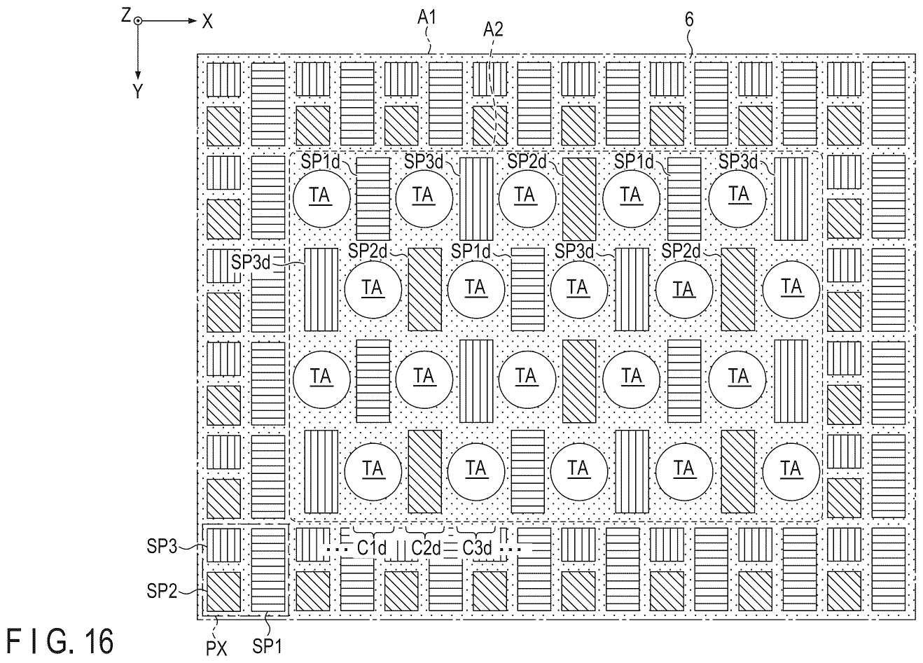

FIG. 16 is a schematic plan view showing a second area A2 and part of a first area A1 which surrounds the second area A2 according to the fifth embodiment. In a manner similar to that of FIG. 4, a partition 6 is shown by the dotted pattern. Subpixels SP1 are shown by the pattern of lateral stripes. Subpixels SP2 are shown by the pattern of diagonal stripes. Subpixels SP3 are shown by the pattern of vertical stripes.

In this embodiment, subpixels SP1, SP2 and SP3 provided in the second area A2 are called subpixels SP1d, SP2d and SP3d, respectively. In the example of FIG. 16, all of subpixels SP1d, SP2d and SP3d are rectangular in a manner similar to that of subpixels SP1, SP2 and SP3. Each subpixel SP1 and each subpixel SP1d have the same size.

However, subpixels SP2d and SP3d have sizes which are different from those of subpixels SP2 and SP3, respectively. Specifically, the sizes of subpixels SP2d and SP3d are larger than those of subpixels SP2 and SP3, respectively. For example, the shapes and sizes of subpixels SP1d, SP2d and SP3d are equal to each other. However, they may be different from each other.

In the example of FIG. 16, the second area A2 includes columns C1d in which each subpixel SP1d and each transmissive area TA are alternately provided in a Y-direction, columns C2d in which each subpixel SP2d and each transmissive area TA are alternately provided in the Y-direction, and columns C3d in which each subpixel SP3d and each transmissive area TA are alternately provided in the Y-direction. The columns C1d, C2d and C3d are repeatedly arranged in an X-direction. The shape of each transmissive area TA is, for example, a circle in a manner similar to that of FIG. 4. However, the shape of each transmissive area TA may be another shape.

### Sixth Embodiment

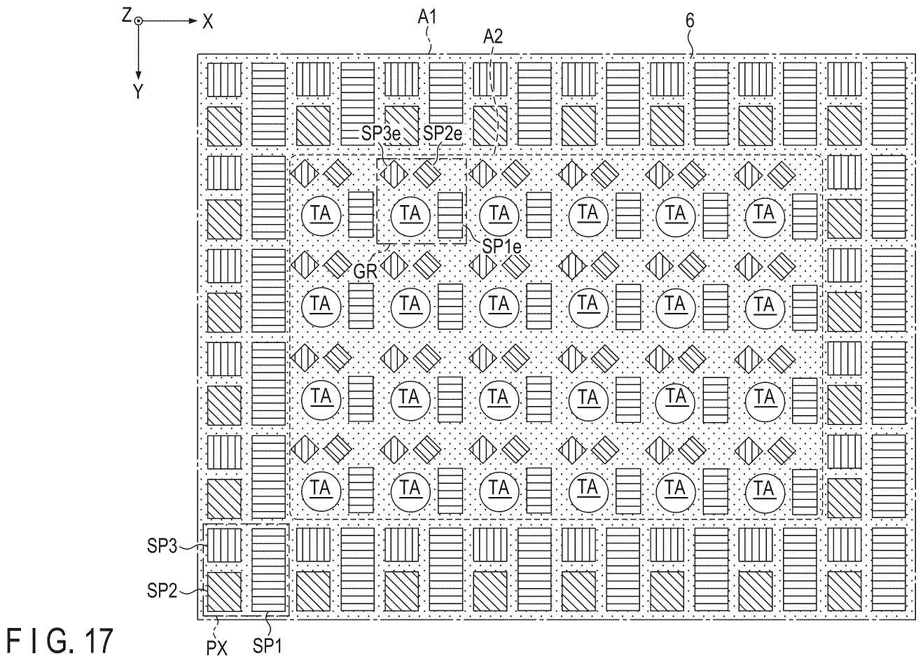

FIG. 17 is a schematic plan view showing a second area A2 and part of a first area A1 which surrounds the second area A2 according to the sixth embodiment. In a manner similar to that of FIG. 4, a partition 6 is shown by the dotted pattern. Subpixels SP1 are shown by the pattern of lateral stripes. Subpixels SP2 are shown by the pattern of diagonal stripes. Subpixels SP3 are shown by the pattern of vertical stripes.

In this embodiment, subpixels SP1, SP2 and SP3 provided in the second area A2 are called subpixels SP1e, SP2e and SP3e, respectively. In the example of FIG. 17, all of subpixels SP1e, SP2e and SP3e are rectangular in a manner similar to that of subpixels SP1, SP2 and SP3. It should be noted that, while the sides of subpixels SP1, SP2, SP3 and SP1e are parallel to an X-direction and a Y-direction, each side of subpixels SP2e and SP3e inclines with respect to the X-direction and the Y-direction. The shape of each transmissive area TA is, for example, a circle in a manner similar to that of FIG. 4. However, the shape of each transmissive area TA may be another shape.

The sizes of subpixels SP1e, SP2e and SP3e are smaller than those of subpixels SP1, SP2 and SP3, respectively. In the example of FIG. 17, the size of each subpixel SP1e is larger than that of each of subpixels SP2e and SP3e. This relationship of the sizes is similar to that of the sizes between each subpixel SP1 and subpixels SP2 and SP3. Thus, in a manner similar to that of the example of FIG. 15, the difference in the display quality between the first area A1 and the second area A2 can be reduced.

A group GR which consists of subpixels SP1e, SP2e and SP3e and the transmissive area TA is repeatedly provided in the X-direction and the Y-direction in the second area A2. The pitch of the groups GR in the X-direction and the Y-direction is equal to the pitch of the pixels PX provided in the first area A1 in the X-direction and the Y-direction.

In other words, in the configuration of FIG. 17, a resolution equal to that of the first area A1 is realized in the second area A2 as well. This configuration enables the reduction in the difference in the display quality between the first area A1 and the second area A2.

The second to sixth embodiments described above show configurations in which each first subpixel provided in the first area A1 has a shape or size which is different from that of each second subpixel provided in the second area A2 and displaying the same color as each first subpixel. In other words, in the second embodiment (FIG. 11), the sizes of blue subpixels SP1 and SP1a are different from each other, and the sizes of green subpixels SP2 and SP2a are also different from each other. In the third embodiment (FIG. 12), the shapes of blue subpixels SP1 and SP1b are different from each other, and the shapes of green subpixels SP2 and SP2b are different from each other, and the shapes of red subpixels SP3 and SP3b are different from each other. In the fourth embodiment (FIG. 15), the shapes of green subpixels SP2 and SP2b are different from each other, and the shapes of red subpixels SP3 and SP3c are also different from each other. In the fifth embodiment (FIG. 16), the sizes of green subpixels SP2 and SP2d are different from each other, and the sizes of red subpixels SP3 and SP3d are also different from each other. In the sixth embodiment (FIG. 17), the sizes of blue subpixels SP1 and SP1e are different from each other, and the sizes of green subpixels SP2 and SP2e are different from each other, and the sizes of red subpixels SP3 and SP3e are different from each other. In addition to these embodiments, various shapes or sizes can be applied to the first subpixels provided in the first area A1 and the second subpixels provided in the second area A2.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
first and second areas each of which includes a plurality of subpixels; and
a partition which includes a conductive lower portion and an upper portion having an end portion protruding from a side surface of the lower portion, and surrounds each of the subpixels, wherein
each of the subpixels includes:
a lower electrode;
an organic layer which covers the lower electrode and emits light based on application of voltage; and
an upper electrode which covers the organic layer and is in contact with the lower portion of the partition,
the second area has a plurality of transmissive areas which are surrounded by the partition and do not overlap the lower electrode, and
a resolution of the second area is lower than a resolution of the first area.

2. The display device of claim 1, further comprising:
an organic insulating layer provided under the lower electrode; and
a rib which covers an end portion of the lower electrode and the organic insulating layer and has a pixel aperture in each of the subpixels, wherein
the organic layer covers the lower electrode through the pixel aperture, and
the partition is provided on the rib.

3. The display device of claim 2, wherein
the transmissive areas overlap the organic insulating layer and the rib.

4. The display device of claim 2, wherein
at least one of the organic insulating layer and the rib has an aperture which overlaps the transmissive area.

5. The display device of claim 1, wherein
the first area does not have the transmissive areas.

6. The display device of claim 1, further comprising a plurality of pixel circuits which apply voltage to the lower electrodes of the subpixels, wherein
the pixel circuit of at least one of the subpixels provided in the second area is provided in the first area.

7. The display device of claim 1, wherein
each of the transmissive areas is circular as seen in plan view.

8. A display device comprising:
first and second areas each of which includes a plurality of subpixels; and
a partition which includes a conductive lower portion and an upper portion having an end portion protruding from a side surface of the lower portion and surrounds each of the subpixels, wherein
each of the subpixels includes:
a lower electrode;
an organic layer which covers the lower electrode and emits light based on application of voltage; and
an upper electrode which covers the organic layer and is in contact with the lower portion of the partition,
the second area has a plurality of transmissive areas which are surrounded by the partition and do not overlap the lower electrode,
the subpixels include:
a first subpixel provided in the first area; and
a second subpixel provided in the second area and displaying a same color as the first subpixel, and
the first subpixel and the second subpixel have shapes or sizes different from each other.

9. The display device of claim 8, wherein
the size of the second subpixel is smaller than the size of the first subpixel.

10. The display device of claim 8, wherein
the size of the second subpixel is larger than the size of the first subpixel.

11. The display device of claim 8, wherein
the first subpixel is rectangular, and
the second subpixel is circular.

12. The display device of claim 8, further comprising:
an organic insulating layer provided under the lower electrode; and
a rib which covers an end portion of the lower electrode and the organic insulating layer and has a pixel aperture in each of the subpixels, wherein
the organic layer covers the lower electrode through the pixel aperture, and
the partition is provided on the rib.

13. The display device of claim 12, wherein
the transmissive areas overlap the organic insulating layer and the rib.

14. The display device of claim 12, wherein
at least one of the organic insulating layer and the rib has an aperture which overlaps the transmissive area.

15. The display device of claim 8, wherein
the first area does not have the transmissive areas.

16. The display device of claim 8, further comprising a plurality of pixel circuits which apply voltage to the lower electrodes of the subpixels, wherein
the pixel circuit of at least one of the subpixels provided in the second area is provided in the first area.

17. The display device of claim 8, wherein
each of the transmissive areas is circular as seen in plan view.

18. A display device comprising:
a lower electrode;
a first organic layer which covers the lower electrode and emits light based on application of voltage;
a second organic layer which is spaced apart from the first organic layer, covers the lower electrode and emits light based on application of voltage;
a partition which includes a conductive lower portion and an upper portion having an end portion protruding from a side surface of the lower portion and is at least partly located between the first organic layer and the second organic layer;
a first upper electrode which covers the first organic layer and is in contact with the lower portion; and
a second upper electrode which covers the second organic layer and is in contact with the lower portion.

19. The display device of claim 18, wherein
the first organic layer and the second organic layer emit light exhibiting a same color based on application of voltage.

20. The display device of claim 18, wherein
the partition has:
a first aperture which overlaps the first organic layer; and
a second aperture which overlaps the second organic layer.
